(19) United States
(12) Patent Application Publication
(10) Pub. No.: US 2024/0264236 A1
(43) Pub. Date: Aug. 8, 2024

(54) ABNORMALITY DETECTION DEVICE, ELECTRIC POWER SOURCE SYSTEM, AND ABNORMALITY DETECTION METHOD

(71) Applicant: MURATA MANUFACTURING CO., LTD., Kyoto (JP)

(72) Inventors: Jusuke SHIMURA, Kyoto (JP); Saori HAYASHI, Kyoyo (JP)

(21) Appl. No.: 18/640,704

(22) Filed: Apr. 19, 2024

Related U.S. Application Data
(63) Continuation of application No. PCT/JP2022/042591, filed on Nov. 16, 2022.

(30) Foreign Application Priority Data
Dec. 28, 2021 (JP) 2021-215035

(51) Int. Cl. G01R 31/3835; G01R 31/36; G01R 31/367

(52) U.S. Cl. CPC G01R 31/3835; G01R 31/3648; G01R 31/367

(57) ABSTRACT

An abnormality detection device is provided and includes a voltage holder, a feature calculator, a data set holder, and a degree-of-abnormality calculator. The voltage holder holds a voltage value of at least one of a maximum value or a minimum value, of a measured voltage, in every fixed time period. The feature calculator calculates a feature that has sensitivity to a voltage spike waveform by processing the voltage value held in the voltage holder. The data set holder holds a data set obtained from a normal secondary battery. The degree-of-abnormality calculator calculates, based on the data set read from the data set holder, a degree of abnormality of the feature calculated by the feature calculator.

### CROSS REFERENCE TO RELATED APPLICATIONS

The present application is a continuation of PCT patent application no. PCT/JP2022/042591, filed on Nov. 16, 2022, which claims priority to Japanese patent application no. 2021-215035, filed on Dec. 28, 2021, the entire contents of which are incorporated herein by reference.

### BACKGROUND

The present application relates to an abnormality detection device, an electric power source system, and an abnormality detection method.

Electric vehicles and hybrid vehicles have been widely used. Power generation devices for solar power generation or wind power generation in which power generation is unstable and necessitates leveling have also been widely used. Such widespread use has rapidly increased demand for various secondary batteries such as a lithium-ion secondary battery.

However, a dendrite can be formed inside a secondary battery, which can cause a micro-short circuit.

### SUMMARY

The present application relates to an abnormality detection device, an electric power source system, and an abnormality detection method.

A neural network is used to detect an abnormality in a secondary battery. The detection based on the neural network can provide insufficient detection accuracy depending on a way in which learning is performed, which can lead to erroneous detection. Nevertheless, it has been difficult for a user to understand a basis on which such a detection result is obtained in the detection based on the neural network, due to an algorithmic property of the detection. It has therefore been difficult to manage a risk in the abnormality detection based on the neural network, which makes it difficult to apply the abnormality detection based on the neural network to a purpose where it is necessary to make a serious determination, for example, involving a human life or a large economic loss. The present technology has been made in view of such circumstances and to provide an abnormality detection device, an electric power source system, and an abnormality detection method for a secondary battery, which make it possible for a user to understand a basis of detection according to an embodiment.

An abnormality detection device according to an embodiment of the present technology includes a voltage measurer, a voltage holder, a feature calculator, a data set holder, and a degree-of-abnormality calculator. The voltage measurer measures a voltage of a secondary battery. The voltage holder holds a voltage value of at least one of a maximum value or a minimum value, of the voltage measured by the voltage measurer, in every fixed time period. The feature calculator calculates a feature that has sensitivity to a voltage spike waveform by processing the voltage value held in the voltage holder. The data set holder holds a data set obtained from a normal secondary battery. The degree-of-abnormality calculator calculates, based on the data set read from the data set holder, a degree of abnormality of the feature calculated by the feature calculator.

An electric power source system according to an embodiment of the present technology includes a secondary battery, a voltage measurer, a voltage holder, a feature calculator, a data set holder, and a degree-of-abnormality calculator. The voltage measurer measures a voltage of the secondary battery. The voltage holder holds a voltage value of at least one of a maximum value or a minimum value, of the voltage measured by the voltage measurer, in every fixed time period. The feature calculator calculates a feature that has sensitivity to a voltage spike waveform by processing the voltage value held in the voltage holder. The data set holder holds a data set obtained from a normal secondary battery. The degree-of-abnormality calculator calculates, based on the data set read from the data set holder, a degree of abnormality of the feature calculated by the feature calculator.

An abnormality detection method according to an embodiment of the present technology includes the following four processes:
(A) measuring a voltage of a secondary battery;
(B) holding a voltage value of at least one of a maximum value or a minimum value, of the voltage that has been measured, in every fixed time period;
(C) calculating a feature that has sensitivity to a voltage spike waveform by processing the voltage value that has been held; and
(D) calculating, based on a data set obtained from a normal secondary battery, a degree of abnormality of the feature.

According to the abnormality detection device, the electric power source system, and the abnormality detection method of the respective embodiments of the present technology, the degree of abnormality is calculated, based on the data set obtained from the normal secondary battery, for the feature obtained from a result of the measuring performed on the secondary battery. It is therefore possible to detect the presence or absence of an abnormality in the secondary battery caused by a micro-short circuit, without using a technique having a high black-box property such as the neural network. Accordingly, it is possible for a user to understand a basis of the detection.

Note that effects of the present technology are not necessarily limited to those described herein and may include any of a series of effects in relation to the present technology.

### BRIEF DESCRIPTION OF THE FIGURES

FIG. 1 is a diagram illustrating an exemplary functional block of electronic equipment according to an embodiment of the present technology.

FIG. 2 is a diagram illustrating an exemplary circuit configuration of a voltage peak detector of FIG. 1.

FIG. 3 is a diagram illustrating an exemplary configuration of an abnormality determiner of FIG. 1.

FIG. 4 is a diagram illustrating an example of a data set DS held by a storage of FIG. 3.

FIG. 5 is a diagram illustrating examples of coordinate groups in a four-dimensional feature space of normal secondary batteries prepared in advance to define the data set DS of FIG. 1.

FIG. 6 is a diagram illustrating an example of an output voltage waveform of the voltage peak detector of FIG. 1 and a feature waveform.

FIG. 7 illustrates a scatter plot matrix of each of features measured in an abnormal secondary battery.

FIG. 8 is a diagram illustrating a degree of similarity between the features each measured in the abnormal secondary battery.

FIG. 9 is a diagram illustrating an example of an output voltage waveform of the voltage peak detector of FIG. 1 measured in the abnormal secondary battery, an example of a degree of abnormality K calculated by a k-nearest neighbor algorithm, and an example of an estimated degree of abnormality K′ determined via the data set DS.

FIG. 10 is a diagram illustrating an example of comparison between the degree of abnormality K directly determined by the k-nearest neighbor algorithm and the estimated degree of abnormality K′ determined via the data set DS.

FIG. 11 is a diagram illustrating an exemplary circuit configuration of a low-pass filter of FIG. 1.

FIG. 12 is a diagram of a simulation space and a dendrite, and a computational mesh that are used in a simulation based on a finite element method.

FIG. 13 is a diagram of a relationship between a DOD and a voltage of a positive electrode that is used in the simulation based on the finite element method.

FIG. 14 is a diagram of lists of values of respective variables used in calculating a cell voltage.

FIG. 15 is a diagram of a simulation result of the cell voltage.

FIG. 16 is an enlarged diagram of a potential difference of FIG. 15.

FIG. 17 is a diagram illustrating a modification of the functional block of the electronic equipment of FIG. 1.

FIG. 18 is a diagram illustrating a modification of the functional block of the electronic equipment of FIG. 1.

FIG. 19 is a diagram illustrating a modification of the functional block of the electronic equipment of FIG. 1.

### DETAILED DESCRIPTION

The present application will be described below in further detail including with reference to the drawings.

A description is given first of a secondary battery to be used in an electric power supply device according to an embodiment of the present technology.

The secondary battery to be used in the present technology may include, for example, a secondary battery of more than approximately several hundred milliamperes-hour that can actually lead to smoking and ignition when an internal short circuit occurs. Examples of the secondary battery of more than approximately several hundred milliamperes-hour include a battery of a laminated-film type and a battery of a cylindrical type. A charge and discharge principle of the secondary battery to be used in the present technology is not particularly limited; however, the secondary battery to be used in the present technology is configured to obtain a battery capacity through, for example, insertion and extraction of an electrode reactant. The secondary battery to be used in the present technology includes, for example, a positive electrode, a negative electrode, and an electrolyte. In the secondary battery to be used in the present technology, a charge capacity of the negative electrode is greater than a discharge capacity of the positive electrode, in order to prevent the electrode reactant from being precipitated on a surface of the negative electrode during charging, for example. In this case, an electrochemical capacity per unit area of the negative electrode is set, for example, to be greater than an electrochemical capacity per unit area of the positive electrode.

The electrode reactant is not particularly limited in kind, and is specifically a light metal such as an alkali metal or an alkaline earth metal. Examples of the alkali metal include lithium, sodium, and potassium. Examples of the alkaline earth metal include beryllium, magnesium, and calcium. A secondary battery that obtains a battery capacity through insertion and extraction of lithium is what is called a lithium-ion secondary battery. In the lithium-ion secondary battery, lithium is inserted and extracted in an ionic state.

Next, a description is given of an issue regarding the secondary battery to be used in the present technology.

In the secondary battery to be used in the present technology, a micro-short circuit can occur between the positive electrode and the negative electrode due to a dendrite generated inside the secondary battery. With an increase in frequency of the occurrence of the micro-short circuit, a possibility that a larger internal short circuit will occur can increase. When the short circuit occurs, Joule heat is generated around a position of the short circuit. Depending on a state of the generation of Joule heat, thermal runaway can occur in the secondary battery. It is therefore important to detect frequent occurrences of the micro-short circuit early.

According to Non-Patent Literature (NPTL) 1 and NPTL 2 described below, when an internal short circuit derived from a dendrite occurs inside a secondary battery, a voltage between terminals changes, and there are two patterns in a behavior of the change. One is a pattern in which the voltage changes in a spike shape, i.e., the voltage drops instantaneously and thereafter recovers immediately. The other is a pattern in which the voltage keeps a lowered state, and the voltage gradually decreases therefrom. A difference between the two patterns derives from whether a state of the internal short circuit is quickly resolved by itself. A case where the internal short circuit state is quickly resolved by itself results in the former pattern and a case where the internal short circuit state is not quickly resolved by itself results in the latter pattern. One cause of the internal short circuit is a dendrite, for example. In this case, the higher the resistance of the dendrite, which serves as an internal short circuit path, is and the more easily the Joule heat is therefore generated, or the smaller a diameter of the dendrite is, the more easily the dendrite is fused, and the more easily the former pattern of the spike shape is observed.
NPTL 1: Lingxi Kong, Yinjiao Xing, Michael G. Pecht, “In-Situ Observations of Lithium Dendrite Growth,” IEEE Access 6, 2018, 8387-8393.
NPTL 2: Mingxuan Zhang, Lishuo Liu, Anna Stefanopoulou, Janson Siegel, Languang Lu, Xiangming He, Minggao Ouyang, “Fusing Phenomenon of Lithium-Ion Battery Internal Short Circuit,” Journal of The Electrochemical Society 164(12), 2017, A2738-A2745.

Online detection of an internal short circuit phenomenon, i.e., internal short circuit detection in a situation in which a battery is coupled to electronic equipment and used, is relatively easy for the latter internal short circuit in which the voltage continues to drop, even if a short-circuit current is low. When multiple batteries are coupled to each other in series, if an imbalance occurs with a focus on the voltages of the respective batteries, there is a high possibility that a minute internal short circuit occurs inside the battery whose voltage is markedly dropping. Even if only a single battery is used in the equipment, it is also possible to perform highly sensitive detection by methods including, without limitation, examining a circuit constant of an equivalent circuit and examining deviation from a battery behavior model prepared in advance.

In contrast, for the former internal short circuit to be observed as a voltage spike, it is difficult to perform the online detection unless a level of the short circuit becomes a certain level of short-circuit. A reason for this is that when the magnitude of the internal short circuit is small, a half-value width of the spike is narrow and can be on the order of microseconds. For detecting such a minute voltage spike, it is necessary to perform voltage measurement with a sufficiently high sampling frequency. However, if the voltage measurement is to be performed through the online detection, the equipment has to include a high-speed AD converter, which increases overall cost of the equipment. This is far from a versatile method.

For example, respective inventions disclosed in the following PTLs 1 and 2 are each a technique of detecting a minute voltage spike.
PTL 1: International Publication No. WO2019/138286
PTL 2: Japanese Unexamined Patent Application Publication No. 2003-009405

The invention disclosed in PTL 1 detects an abnormality in a secondary battery based on a neural network. It is difficult to understand a basis on which such a detection result is obtained in the detection based on the neural network. Accordingly, even when an abnormality in the secondary battery is detected, it is difficult for a user to rely on the detection result based on the neural network.

Assume that the invention disclosed in PTL 1 is used for detection of an abnormality in a lithium-ion battery mounted on an electric aircraft. In this case, it is probably difficult to determine whether an emergency landing should be immediately performed even if a battery abnormality is detected during flight. This is because a basis on which the determination based on the neural network is made is unclear, and performing the emergency landing causes a considerable economic loss. If the emergency landing is performed with the basis for the emergency landing being unclear, a detailed analysis of the battery may be performed after the emergency landing. The detailed analysis may reveal that no abnormality in particular leading to danger has been present, and that the abnormality has been in fact a usual micro-short circuit that can occur even in a normal battery. Such a situation is often inexcusable.

It is necessary that software installed in an aircraft be developed based on DO-178C, a standard certified by an organization such as FAA (Federal Aviation Administration) or EASA (European Aviation Safety Organization). An aircraft having software installed therein that does not comply with DO-178C cannot obtain airworthiness certification (corresponding to “automobile inspection” in aircraft) and cannot fly in Japan. The current DO-178C does not allow the software to have any black-box property. It is therefore not possible to install software that performs the determination based on the neural network in the aircraft as of present time.

The invention disclosed in PTL 2 detects an abnormality in a secondary battery by comparing a measured voltage value with a threshold. However, a range of a voltage local minimum value in terms of voltage drop due to a minute short circuit depends on an internal resistance of the battery, and the internal resistance depends on, for example, a degree of degradation and a temperature. Thus, if the threshold is to be used as a reference for determining the presence or absence of an abnormality, it is necessary to separately prepare, for example, a measurer to measure the internal resistance of the battery, and to sequentially change the threshold using a value of the internal resistance that has been obtained. However, in the invention disclosed in PTL 2, a basis for a method of setting the threshold is insufficient, and it is difficult for a user to use a detection result in a serious determination.

Accordingly, the inventors of the present application propose an abnormality detection device, an electric power source system, and an abnormality detection method that allow a basis of the detection of an abnormality in a secondary battery caused by a micro-short circuit to be understandable by a user.

Next, a configuration of electronic equipment 1 according to an embodiment of the present technology will be described.

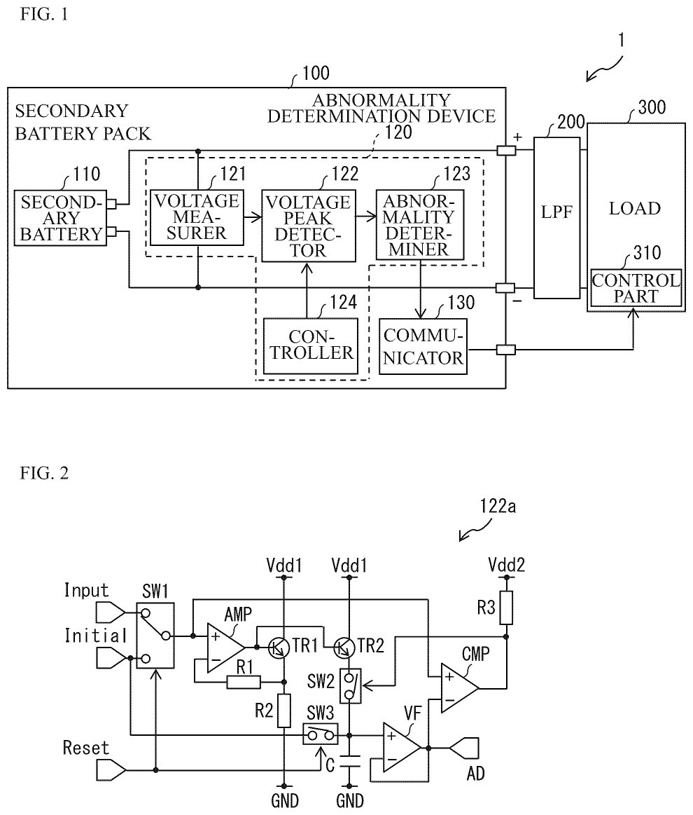

FIG. 1 illustrates an exemplary functional block of the electronic equipment 1 according to the present embodiment. The electronic equipment 1 includes, for example, a secondary battery pack 100 as illustrated in FIG. 1. The electronic equipment 1 includes, for example, the secondary battery pack 100, a low-pass filter 200, and a load 300 as illustrated in FIG. 1. In the electronic equipment 1, the secondary battery pack corresponds to a specific example of an “electric power source system” according to the present technology.

The load 300 is a device that has various roles in the electronic equipment 1. The load 300 includes, for example, a control part 310 (e.g., a MCU (Micro Controller Unit)) that controls the device. To the load 300, the secondary battery pack 100 that supplies electric power to the load 300 is coupled. The load 300 and the secondary battery pack 100 are electrically coupled to each other by wiring. Among the wiring coupling the load 300 and the secondary battery pack 100 to each other, the low-pass filter 200 is interposed between a voltage measurer 121 and the load 300. The low-pass filter 200 is omittable on an as-needed basis.

The secondary battery pack 100 includes a secondary battery 110. The secondary battery 110 included in the secondary battery pack 100 may be, for example, assembled batteries including multiple secondary batteries coupled in parallel with each other or multiple secondary batteries coupled in series with each other. The secondary battery 110 includes, for example, a lithium-ion battery.

The secondary battery pack 100 further includes an abnormality determination device 120 and a communicator 130. The abnormality determination device 120 corresponds to a specific example of an “abnormality determination device” of the present technology. The abnormality determination device 120 is provided between the secondary battery 110 and the low-pass filter 200. The abnormality determination device 120 determines an abnormality in the secondary battery 110 and outputs a result of the determination to the communicator 130. The communicator 130 is a communication interface that transmits the determination result inputted from the abnormality determination device 120 to, for example, the control part 310. As used herein, the abnormality in the secondary battery 110 refers to thermal runaway of the secondary battery 110 due to a short circuit between a positive electrode and a negative electrode.

The abnormality determination device 120 includes, for example, the voltage measurer 121, a voltage peak detector 122, an abnormality determiner 123, and a controller 124.

The voltage measurer 121 is coupled to the positive electrode and the negative electrode of the secondary battery 110, and measures an analog voltage (i.e., an output voltage of the secondary battery 110) between the positive electrode and the negative electrode of the secondary battery 110. Hereinafter, the output voltage of the secondary battery 110 is referred to as a present-time voltage Vc. The voltage measurer 121 outputs the present-time voltage Vc obtained by the measurement to the voltage peak detector 122.

The voltage peak detector 122 detects a voltage spike included in the present-time voltage Vc measured by the voltage measurer 121. The voltage peak detector 122 holds a maximum voltage Vu of the detected voltage spike and a minimum voltage Vl of the detected voltage spike, and outputs the maximum voltage Vu and the minimum voltage Vl to the abnormality determiner 123 at a predetermined frequency.

Here, the present-time voltage Vc measured by the voltage measurer 121 may include the voltage spike caused by the above-described micro-short circuit. A half-value width of the voltage spike is often on the order of micro-seconds. Accordingly, in order to make it possible to detect an instantaneous voltage spike having a half-value width of 1 μs by an inexpensive AD converter having a low sampling frequency, the voltage peak detector 122 includes a peak hold circuit in which a response speed is increased by being coupled to a current-feedback charge circuit. The voltage peak detector 122 includes at least one of a peak hold circuit that holds a peak voltage (the maximum voltage Vu) of a voltage spike having a peak in a positive direction or a peak hold circuit that holds a peak voltage (the minimum voltage Vl) of a voltage spike having a peak in a negative direction. It is thus possible for the voltage peak detector 122 to sequentially output, for example, the maximum voltage Vu and the minimum voltage Vl in every 50 ms at a frequency of 20 times in one second (that is, 20 Hz).

FIG. 2 illustrates an exemplary circuit configuration of a peak hold circuit 122a included in the voltage peak detector 122. The peak hold circuit 122a holds the maximum voltage Vu. The peak hold circuit 122a includes three input terminals (an Input terminal, an Initial terminal, and a Reset terminal) and one output terminal (an AD terminal). The present-time voltage Vc is inputted to the Input terminal and the Initial terminal. A reset signal is inputted to the Reset terminal. The reset signal is temporarily turned high every time period ΔT (e.g., 50 ms) longer than the half-value width of the voltage spike. The reset signal is outputted from the controller 124. The AD terminal is coupled to the abnormality determiner 123. The controller 124 includes, for example, a MCU (Micro Controller Unit), and outputs the reset signal, which is temporarily turned high every time period ΔT (e.g., 50 ms), to the voltage peak detector 122. It is thus possible for the voltage peak detector 122 to sequentially output at least one of the maximum voltage Vu or the minimum voltage Vl in every time period ΔT (e.g., 50 ms) at a frequency of ΔT times in one second (i.e., 1/ΔT [Hz] (e.g., 20 Hz)).

The peak hold circuit 122a further includes three switches SW1, SW2, and SW3, an operational amplifier AMP, a voltage follower VF, a comparator CMP, two transistors TR1 and TR2, a capacitor C, and three resistors R1, R2, and R3.

The switch SW1 is a two-input one-output switch. The switch SW1 has one of input terminals coupled to the Input terminal, another of the input terminals coupled to the Initial terminal, and an output terminal coupled to an input terminal (+) of the operational amplifier AMP. A signal that controls on/off of the switch SW1 is inputted from the Reset terminal. The switch SW2 is a one-input one-output switch. The switch SW2 has an input terminal coupled to an emitter of the transistor TR2, and an output terminal coupled to an output terminal of the switch SW3, to an input terminal (+) of the operational amplifier AMP, and to the capacitor C. A signal that controls on/off of the switch SW2 is inputted from an output terminal of the comparator CMP. The switch SW3 is a one-input one-output switch. The switch SW3 has an input terminal coupled to the Initial terminal, and the output terminal coupled to the output terminal of the switch SW2, to the input terminal (+) of the operational amplifier AMP, and to the capacitor C. A signal that controls on/off of the switch SW3 is inputted from the Reset terminal.

The operational amplifier AMP has the input terminal (+) coupled to the output terminal of the switch SW1 and to an input terminal (+) of the comparator CMP, and has an input terminal (−) coupled to an emitter of the transistor TR1 via the resistor R1 and to the resistor R2. The operational amplifier AMP has an output terminal coupled to a base of the transistor TR1 and to a base of the transistor TR2.

The voltage follower VF has the input terminal (+) coupled to the respective output terminals of the switches SW2 and SW3 and to the capacitor C, has an input terminal (−) coupled to an output terminal of the voltage follower VF, and has the output terminal coupled to an input terminal (−) of the comparator CMP and to the AD terminal. The comparator CMP has the input terminal (+) coupled to the output terminal of the switch SW1 and to the output terminal of the operational amplifier AMP, has the input terminal (−) coupled to the output terminal of the voltage follower VF and to the AD terminal, and has an output terminal coupled to a power supply line Vdd2 via the resistor R3.

The transistor TR1 has the base coupled to the output terminal of the operational amplifier AMP and to the base of the transistor TR2, has a collector coupled to a power supply line Vdd1, and has the emitter coupled to the input terminal (−) of the operational amplifier AMP via the resistor R1 and to a ground via the resistor R2. The transistor TR2 has the base coupled to the output terminal of the operational amplifier AMP and to the base of the transistor TR1, has a collector coupled to the power supply line Vdd1, and has the emitter coupled, via the switch SW2, to the output terminal of the switch SW3, to the input terminal (+) of the voltage follower VF, and to the capacitor C. The capacitor C has one end coupled to the respective output terminals of the switches SW2 and SW3 and to the input terminal (+) of the voltage follower VF, and has another end coupled to the ground.

In the peak hold circuit having such a circuit configuration, when the Reset terminal is set to high, the voltage (the present-time voltage Vc) of the Initial terminal is directly applied to the capacitor C. A peak hold voltage (the maximum voltage Vu in 50 ms) is outputted from the AD terminal. The voltage generated by electric charge stored in the capacitor C corresponds to the peak hold voltage. The peak hold voltage is read by the voltage follower VF and is compared with the present-time voltage Vc by the comparator CMP. At this time, when the peak hold voltage is lower than the present-time voltage Vc, the switch SW2 is turned on and the electric charge of the capacitor C is adjusted. The switch SW2 leading to the capacitor C is provided before the transistor TR2 whose current is controlled by a current mirror. A value of the current is so adjusted by the transistor TR1 and the operational amplifier AMP that are current sources as to be larger as the present-time voltage Vc is higher.

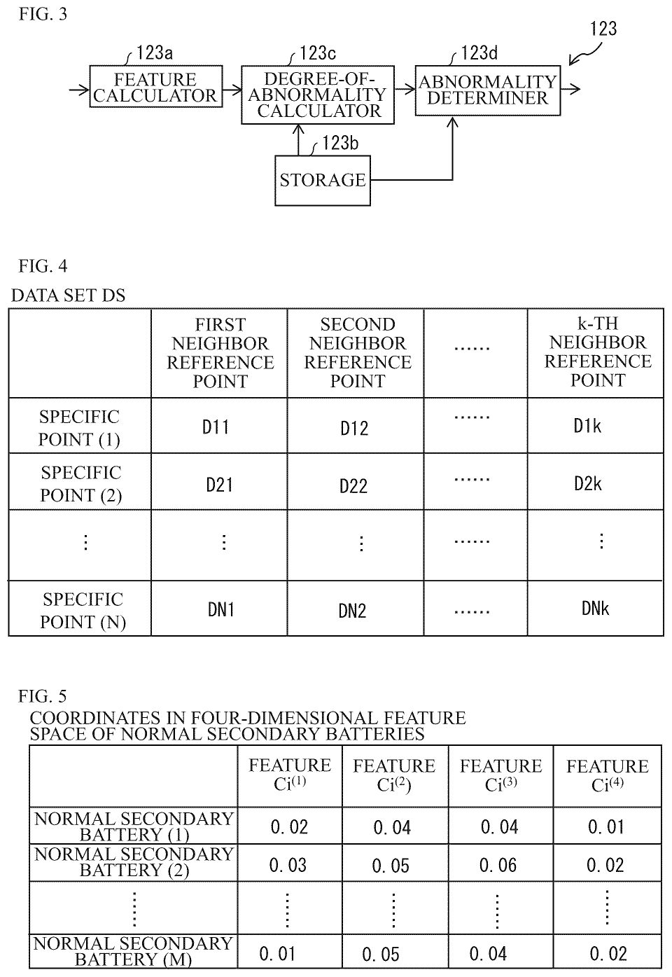

The abnormality determiner 123 determines, based on a result of the detection of the voltage spike (the maximum voltage Vu and the minimum voltage Vl) obtained by the voltage peak detector 122, whether the secondary battery 110 has a risk of abnormality occurrence. As illustrated in FIG. 3, the abnormality determiner 123 includes, for example, a feature calculator 123a, a storage 123b, a degree-of-abnormality calculator 123c, and an abnormality determiner 123d.

The feature calculator 123a calculates a feature that has sensitivity to a voltage spike waveform by processing a voltage value (each of the maximum voltage Vu and the minimum voltage Vl) held in the voltage peak detector 122. The feature calculator 123a calculates, as such a feature, each of the following four kinds of features Cᵢ⁽¹⁾, Cᵢ⁽²⁾, Cᵢ⁽³⁾, and Cᵢ⁽⁴⁾. In the following equation, the maximum voltage Vu is referred to as an upper limit voltage Uᵢ, Uᵢ₊₁, or Uᵢ₋₁, and the minimum voltage Vl is referred to as a lower limit voltage Lᵢ, Lᵢ₊₁, or Lᵢ₋₁. Suffixes “i”, “i+1”, and “i−1” represent a temporal context.

(First Feature Cᵢ⁽¹⁾)

$${C}_{i}^{( 1 )} = 1 / ( 1 + exp \{ - 5 \times 1 {0}^{- 4} \times {S}_{i} \times {B}_{i} \times {M}_{i} \} + 3 )$$

$${S}_{i} = exp \{ X / {Y}_{i} \} - 1$$

$${B}_{i} = {Y}_{i} / ( max ( {Z}_{i} , {10}^{- 5} )$$

$${M}_{i} = {Y}_{i} / ( max ( {V}_{i} + {W}_{i} , {10}^{- 5} )$$

$${X}_{i} = - {U}_{i - 1} + 2 {U}_{i} - {U}_{i + 1} - 3 {L}_{i - 1} + 6 {L}_{1} - {L}_{i + 1}$$

$${Y}_{i} = {U}_{i} + {L}_{i}$$

$${Z}_{i} = \vert {U}_{i - 1} - {L}_{i - 1} - {U}_{i} + {L}_{i} + {U}_{i + 1} - {L}_{i + 1} \vert$$

$${V}_{i} = {U}_{i + 1} + {U}_{i - 1}$$

$${W}_{i} = {L}_{i + 1} + {L}_{i - 1}$$

A background of the voltage spike caused by the internal short circuit includes the following three characteristics.
(1) The upper limit voltage Uᵢ first increases and thereafter decreases, and the lower limit voltage Lᵢ first decreases and thereafter increases.
(2) At a location where the upper limit voltage Uᵢ and the lower limit voltage Lᵢ greatly differ from each other, the spike waveform is buried in the first place, which makes it difficult to see the spike waveform.
(3) At a location where a change in a voltage of a baseline is large, it is difficult to observe the spike waveform in the first place.

Effects of the respective characteristics are calculated as a spike parameter Si, a burying parameter Bi, and a masking parameter Mi defined by the equations above. Thereafter, a product of these parameters (Sᵢ×Bᵢ×Mᵢ) is calculated, and is further compressed by a sigmoid function to be outputted as a value within a range from greater than 0 to less than 1 to thereby obtain the feature Cᵢ⁽¹⁾.

(Second Feature Cᵢ⁽²⁾)

$${C}_{i}^{( 2 )} = {σ}_{U 1 , i} \times {σ}_{U 2 , i} \times {σ}_{L 1 , i} \times {σ}_{L 2 , i}$$

$${σ}_{U 1 , i} 1 = 1 / ( 1 + exp ( - {α}_{i} / \vert {H}_{i} \vert + {10}^{- 4} ) )$$

$${σ}_{U 2 , i} = 1 / ( 1 + exp ( {α}_{i + 1} / \vert {H}_{i} \vert + {10}^{- 4} ) )$$

$${σ}_{L 1 , i} = 1 / ( 1 + exp ( {β}_{i} \vert {H}_{i} \vert + {10}^{- 4} ) )$$

$${σ}_{L 2 , i} = 1 / ( 1 + exp ( - {β}_{i + 1} / \vert {H}_{i} \vert + {10}^{- 4} ) )$$

$${α}_{i} = {U}_{i} - {U}_{i - 1}$$

$${β}_{i} = {L}_{i} - {L}_{i - 1}$$

The feature Cᵢ⁽²⁾ represents, in another mathematical expression, the three characteristics observed in the voltage spike waveform caused by the internal short circuit. “Hi” is a parameter that increases as the baseline is tilted and as the upper limit voltage and the lower limit voltage greatly differ from each other. “σ_{U1,i}”, “σ_{U2,i}”, “σ_{L1,i}”, and “σ_{L2,i}” are respectively a parameter for determining whether the upper limit voltage first increases, a parameter for determining whether the upper limit voltage thereafter decreases, a parameter for determining whether the lower limit voltage first decreases, and a parameter for determining whether the lower limit voltage thereafter increases.

(Third Feature Cᵢ⁽³⁾)

$${C}_{i}^{( 3 )} = 1 / ( 1 + exp ( - {d}_{i} + 5 ) )$$

$${d}_{i} = ( ( {L}_{i} - {b}_{L , i} ) - ( {U}_{i} - {b}_{U , i} ) ) / ( max ( {G}_{U , i} + {G}_{L , i} , {10}^{- 5} ) )$$

$$\begin{matrix}[ Math . 1 ] & \\ {G}_{U , i} = \sqrt{{\sum }_{j ∈ A}^{6} \frac{{( {U}_{i + j} - {\overline{U}}_{i + j} )}^{2}}{4}} & Math . 1\end{matrix}$$

$$\begin{matrix}[ Math . 2 ] & \\ {G}_{L , i} = \sqrt{{\sum }_{j ∈ A}^{6} \frac{{( {L}_{i + j} - {\overline{L}}_{i + j} )}^{2}}{4}} & Math . 2\end{matrix}$$

$$\begin{matrix}[ Math . 3 ] & \\ {\overline{U}}_{i + j} = {a}_{U , i} j + {b}_{U , i} where {a}_{U , i} = {\sum }_{j ∈ A}^{6} \frac{{jU}_{i + j}}{28} , {b}_{U , i} = {\sum }_{j ∈ A}^{6} \frac{{U}_{i + j}}{6} & Math . 3\end{matrix}$$

$$\begin{matrix}[ Math . 4 ] & \\ {\overline{L}}_{i + j} = {a}_{L , i} j + {b}_{L , i} where {a}_{L , i} = {\sum }_{j ∈ A}^{6} \frac{{jL}_{i + j}}{28} , {b}_{L , i} = {\sum }_{j ∈ A}^{6} \frac{{L}_{i + j}}{6} & Math . 4\end{matrix}$$

$$A = \{ - 3 , - 2 , - 1 , 1 , 2 , 3 \}$$

The features Cᵢ⁽¹⁾ and Cᵢ⁽²⁾ are each susceptible to noise, and each tend to return a large value when the upper limit voltage first increases and thereafter decreases and the lower limit voltage first decreases and thereafter increases due to the noise. Cᵢ⁽³⁾ is created as a feature that does not include such a tendency. For each of the upper limit voltage and the lower limit voltage, a regression line is calculated first based on a total of six points which do not include corresponding one of the upper limit voltage or the lower limit voltage itself, i.e., three points before and three points after the corresponding one of the upper limit voltage or the lower limit voltage itself. Thereafter, standard errors G_{U}, and G_{L,i} are each obtained between the regression line and the six points. It is possible to determine whether it is noise by determining whether a point of the upper limit voltage or the lower limit voltage itself is sufficiently larger than the corresponding one of the standard errors. Accordingly, a distance dᵢ between the point of the upper limit voltage or the lower limit voltage itself and an intercept of the regression line is determined with a sign, the resultant is divided by the sum of the respective standard errors of the upper limit voltage and the lower limit voltage, and lastly, the resultant is compressed by the sigmoid function to thereby obtain Cᵢ⁽³⁾.

(Fourth Feature Cᵢ⁽⁴⁾)

$${C}_{i}^{( 4 )} = 1 / ( 1 + exp \{ - 500 ( {p}_{i} + {q}_{i} ) + 3 \} )$$

$$\begin{matrix}[ Math . 5 ] & \\ {p}_{i} = 2 r ( {U}_{i} - \frac{{U}_{i - 1} + {U}_{i + 1}}{2} ) \cdot \frac{1}{\sqrt{4 {r}^{2} + {( {U}_{i + 1} - {U}_{i - 1} )}^{2}}} & Math . 5\end{matrix}$$

$$\begin{matrix}[ Math . 6 ] & \\ {q}_{i} = - 2 r ( {L}_{i} - \frac{{L}_{i - 1} + {L}_{i + 1}}{2} ) \cdot \frac{1}{\sqrt{4 {r}^{2} + {( {L}_{i + 1} - {L}_{i - 1} )}^{2}}} & Math . 6\end{matrix}$$

where r=Δt[s]/25[s/V]=0.05/25=0.002

The features Cᵢ⁽¹⁾ and Cᵢ⁽²⁾ are each designed to be smaller in value unconditionally at a location where a change in a change in the voltage of the baseline is large. In practice, however, this assumption may be too strict. It is Cᵢ⁽⁴⁾ that is a feature prepared to allow detection to be performed to some extent even if the change in the voltage of the baseline is large. First, a triangle is drawn by connecting a nearest neighbor point before a relevant point itself, a nearest neighbor point after the relevant point itself, and the relevant point itself, following which a length of a perpendicular line from the relevant point itself to an oblique side is determined. Note that the length has a sign, and the length is set to have a positive sign when the point of the upper limit voltage is on an upper side of the triangle and when the point of the lower limit voltage is on a lower side of the triangle. A length pᵢ of the perpendicular line determined based on the upper limit voltage and a length qᵢ of the perpendicular line determined based on the lower limit voltage are added, and the resultant is compressed by the sigmoid function to thereby obtain Cᵢ⁽⁴⁾. In calculating the length, a parameter “r” describing a relationship between a voltage axis and a time axis is used. The parameter “r” is determined by dividing a measurement data interval Δt by a hyperparameter of a dimension of [s/V].

Incidentally, each of the four kinds of features Cᵢ⁽¹⁾, Cᵢ⁽²⁾, Cᵢ⁽³⁾, and Cᵢ⁽⁴⁾ is compressed by the sigmoid function into an interval (0, 1) that is larger than 0 and smaller than 1. A feature space that has a four-dimensional interval has a shape of a four-dimensional hypercube in which the respective sides all have lengths of 1 and are orthogonal to each other. In the k-nearest neighbor algorithm, work of placing a plot point in the feature space and calculating the distance is carried out. It is therefore important to grasp a maximum value of the distance for understanding a sense of the distance. The maximum value is a distance of a diagonal line of the four-dimensional hypercube, i.e., 2. However, because the feature space is an open interval including no boundary, it is not exactly 2. Accordingly, a range of the value determined by the k-neighbor algorithm is a half-open interval that is a left-closed right-open interval [0, 2) of greater than or equal to 0 and less than 2.

The storage 123b holds a data set DS as illustrated in FIG. 4. In defining the data set DS, first, the four-dimensional feature space having the four kinds of features Cᵢ⁽¹⁾, Cᵢ⁽²⁾, Cᵢ⁽³⁾, and Cᵢ⁽⁴⁾ as respective dimensions is defined. Further, in the four-dimensional feature space, multiple (N-number of) specific points (1) to (N) are defined. The multiple (N-number of) specific points (1) to (N) take, for example, any of values {0.05, 0.15, 0.25, 0.35, 0.45, 0.55, 0.65, 0.75, 0.85, 0.95} in each of the dimensions in the four-dimensional feature space. In this case, the multiple (N-number of) specific points are so set as to take values in all possible combinations as coordinates, and the number N of specific points is 10⁴=10000.

Further, in defining the data set DS, coordinates in the four-dimensional feature space of the multiple (M-number of) normal secondary batteries illustrated in FIG. 5 are prepared. Hereinafter, the coordinates are referred to as “coordinates of reference points”. The normal secondary batteries are each a secondary battery in which the voltage spike caused by the internal short circuit has not occurred (that is, normal). The coordinates of the multiple (M-number of) reference points are, so to say, teaching data indicating a normal state. The coordinates of the reference points include the four kinds of features Cᵢ⁽¹⁾, Cᵢ⁽²⁾, Cᵢ⁽³⁾, and Cᵢ⁽⁴⁾ obtained from the normal secondary battery. Further, in defining the data set DS, for each of the specific points, first to k-th nearest reference points in terms of a distance to the specific point are selected from the coordinates of the multiple (M-number of) reference points.

As illustrated in FIG. 4, for example, the data set DS includes distance data (for example, D11, D12, . . . ) from the specific point to each of the reference points (a first neighbor reference point, a second neighbor reference point, . . . , a k-th neighbor reference point) for each specific point. The distance data is a parameter indicating how similar a secondary battery having a feature represented by the coordinates of each specific point (hereinafter referred to as a “specific secondary battery”) is to a feature of the normal secondary battery represented by the coordinates of each reference point. A smaller value of the distance data indicates that the specific secondary battery is more similar to the feature of the normal secondary battery, and conversely, a larger value of the distance data indicates that the specific secondary battery is less similar to the feature of the normal secondary battery. Accordingly, when a threshold based on which whether the specific secondary battery is the normal secondary battery or the secondary battery has the risk of abnormality occurrence is to be determined is set, if the distance data is smaller than the set threshold, it is possible to determine that the secondary battery corresponding to the distance data is normal. In contrast, if the distance data is larger than or equal to the set threshold, it is possible to determine that the secondary battery corresponding to the distance data has the risk of abnormality occurrence. In other words, the distance data indicates a degree of abnormality of the secondary battery (the four kinds of features Cᵢ⁽¹⁾, Cᵢ⁽²⁾, Cᵢ⁽³⁾, and Cᵢ⁽⁴⁾. Accordingly, the data set DS includes the degree of abnormality of each of the multiple specific points in the four-dimensional feature space. The degree of abnormality is derived by the k-nearest neighbor algorithm based on m-number of kinds of features obtained from each of the normal secondary batteries in the four-dimensional feature space. The threshold may be stored in the storage 123b.

The degree-of-abnormality calculator 123c calculates, based on the data set DS read from the storage 123b, the degree of abnormality of the four kinds of features Cᵢ⁽¹⁾, Cᵢ⁽²⁾, Cᵢ⁽³⁾, and Cᵢ⁽⁴⁾ calculated by the feature calculator 123a. The degree-of-abnormality calculator 123c uses the data set DS each time the degree-of-abnormality calculator 123c calculates the degree of abnormality. The degree-of-abnormality calculator 123c calculates, based on the degree of abnormality of each of the specific points included in the data set DS, the degree of abnormality of the four kinds of features Cᵢ⁽¹⁾, Cᵢ⁽²⁾, Cᵢ⁽³⁾, and Cᵢ⁽⁴⁾ calculated by the feature calculator 123a.

When coordinates (hereinafter referred to as “coordinates of a determination target point”) in the four-dimensional feature space of the secondary battery calculated by the feature calculator 123a match the specific point, the degree-of-abnormality calculator 123c sets a degree of abnormality of the specific point matching the determination target point as a degree of abnormality of the determination target point. When the determination target point does not match the specific point, the degree-of-abnormality calculator 123c performs, for example, linear interpolation in the four-dimensional feature space based on coordinates of multiple specific points that are located in the vicinity of the determination target point, thereby calculating the degree of abnormality of the determination target point. Note that, when the determination target point does not match the specific point, the degree-of-abnormality calculator 123c may set, in the four-dimensional feature space, a degree of abnormality of the specific point closest to the determination target point as the degree of abnormality of the determination target point.

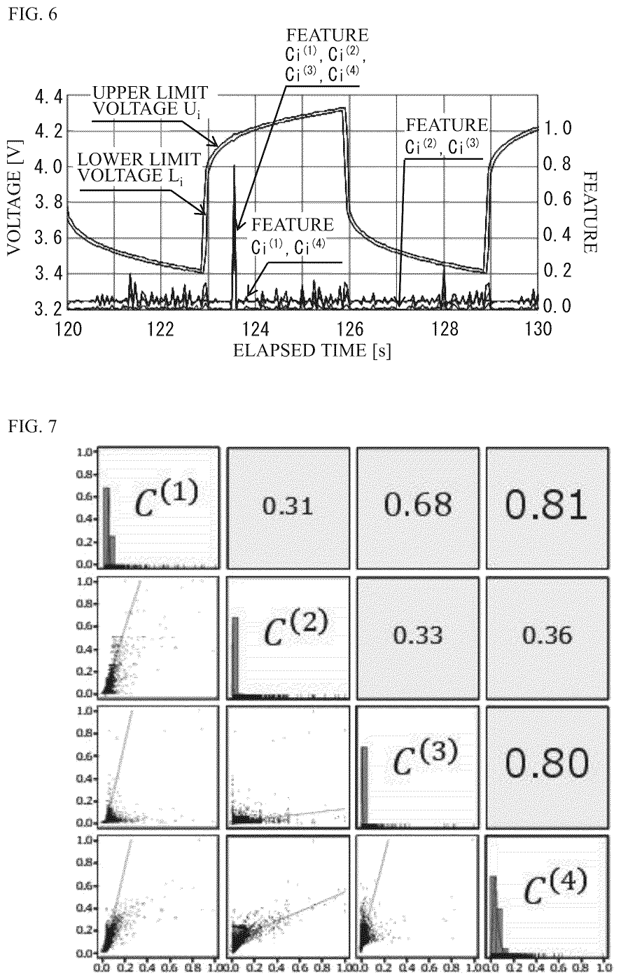

FIG. 6 illustrates a result of passing of a rectangular current of ±15 A through an abnormal battery. FIG. 6 extracts only a part, in terms of elapsed time, from 120 seconds to 130 seconds out of an experiment for a total of approximately 30 minutes. At a location of 123.5 seconds, a waveform is observed in which the upper limit voltage Uᵢ protrudes on an upper side and the lower limit voltage Lᵢ protrudes on a lower side. Such a waveform is considered to be the voltage spike caused by the internal short circuit. FIG. 6 also illustrates values of the respective features. FIG. 6 indicates that, at the location of 123.5 seconds, all the features have large values, while at other locations they have generally small values. It is thus confirmed that all the features are highly sensitive to the voltage spike waveform that is considered to be caused by the internal short circuit.

Using the four features in this case is based on an idea that the four features are detected with high sensitivity in any baseline waveform, and are thus in a complementary relationship, that is, defects of Cᵢ⁽¹⁾ and Cᵢ⁽²⁾ in terms of sensitivity are complemented by Cᵢ⁽³⁾ and Cᵢ⁽⁴⁾. However, based on what is illustrated in FIG. 6, the four features are all large in one location, and are all small in another location, which gives no impression that the four features are in the complementary relationship.

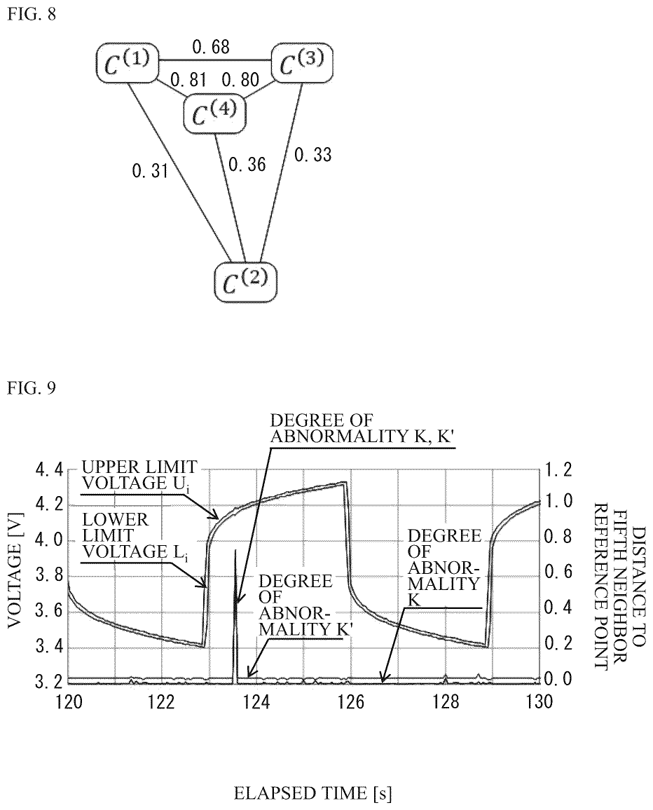

FIG. 7 illustrates a scatter plot matrix of each of the features. FIG. 8 illustrates a diagram of a degree of similarity. The scatter plot matrix refers to a list of two-dimensional scatter plots and two-dimensional correlation coefficients of all combinations in order to confirm a relationship between pieces of data of three or more dimensions. Further, although the diagram of the degree of similarity is a display method that is not usually used in statistics, it is presented for ease of intuitive understanding. The diagram is so illustrated that the higher the correlation coefficient, the closer a distance (the distance is not exact).

Seeing this, FIG. 8 reveals that a result to be derived from Cᵢ⁽⁴⁾ is relatively similar to a result to be derived from Cᵢ⁽¹⁾ or Cᵢ⁽³⁾, meanwhile, Cᵢ⁽²⁾ is away from any of other features, that is, is different from any of the other features in behavior. It has been described that the features are not much in the complementary relationship based on FIG. 6. However, FIG. 7 re-verifies that a correlative relationship between Cᵢ⁽¹⁾ and Cᵢ⁽³⁾ and a correlative relationship between Cᵢ⁽¹⁾ and Cᵢ⁽⁴⁾ are actually high. The idea has been described that the defects of Cᵢ⁽¹⁾ and Cᵢ⁽²⁾ in terms of sensitivity are complemented by Cᵢ⁽³⁾ and Cᵢ⁽⁴⁾. Actually, however, Cᵢ⁽²⁾ behaves relatively independently and complements Cᵢ⁽¹⁾, Cᵢ⁽³⁾, and Cᵢ⁽⁴⁾ that have similar behavior. In terms of whether Cᵢ⁽¹⁾, Cᵢ⁽³⁾, and Cᵢ⁽⁴⁾ are independent or dependent of each other, the fact that the correlation coefficient of 0.81 at most indicates a sufficiently independent relationship between them as for data created by the above-described method. It may thus be said that there is significance in existence of all features.

### (Calculation of Degree of Abnormality by K-Nearest Neighbor Algorithm)

FIG. 9 illustrates a result of the degree of abnormality of the abnormal battery calculated by the k-nearest neighbor algorithm, with use of a feature obtained by passing of a rectangular current of ±15 A through the normal battery, as the teaching data indicating the normal state. FIG. 9 illustrates not only a degree of abnormality K determined by the ordinary k-nearest neighbor algorithm but also an estimated degree of abnormality K′ determined via the data set DS.

In the features illustrated in FIG. 6, noisy waveforms are observed in parts other than the part at 123.5 seconds. However, the degree of abnormality K and the estimated degree of abnormality K′ illustrated in FIG. 9 are almost flat in the parts other than the part at 123.5 seconds, that is, they are stable. In terms of the degree of abnormality K and the estimated degree of abnormality K′, the parts other than the part at 123.5 seconds are approximately zero, which means that the parts other than the part at 123.5 seconds have a very ordinary waveform often observed in normal batteries. For the part at 123.5 seconds, the degree of abnormality K and the estimated degree of abnormality K′ each have a value exceeding 0.6. A length of 0.6 with respect to the maximum length of 2 is 30%. This means that the degree of abnormality K and the estimated degree of abnormality K′ each exceed 30% of the maximum length of 2, which is a sufficiently long distance, i.e., the degree of abnormality K and the estimated degree of abnormality K′ are each high in sensitivity and accuracy.

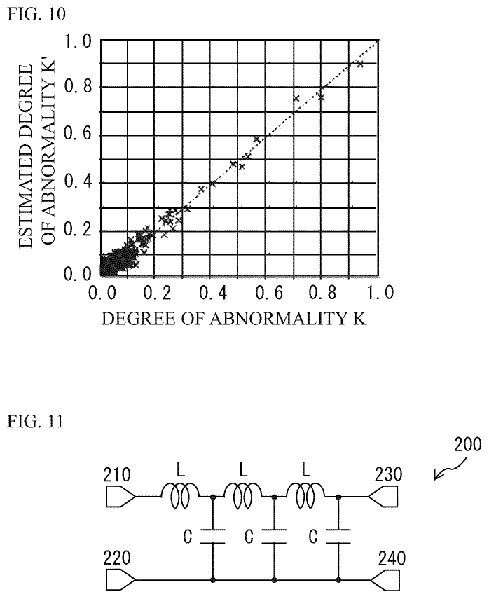

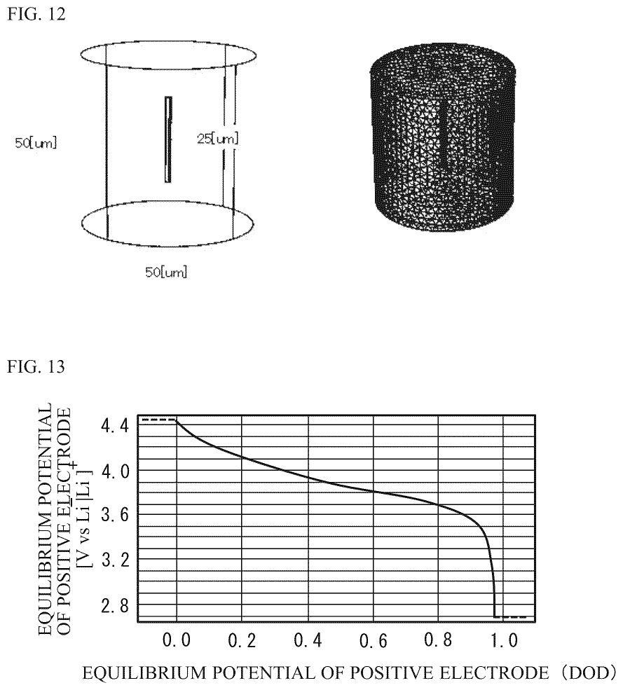

FIG. 10 illustrates comparison between the degree of abnormality K directly determined by the k-nearest neighbor algorithm and the estimated degree of abnormality K′ determined via the data set DS. Note that about 36000 plots are all included here. In order to check a degree of correspondence between the degree of abnormality K and the estimated degree of abnormality K′, the square of the difference is calculated for all pieces of data, and the square root of the average value is determined. The resultant value is 0.030, which reveals that the estimated degree of abnormality K′ has an estimation error of 0.030. This is 1.5% of 2, the maximum length of the feature space, which is an estimated error that is generally considered sufficiently small, although it is necessary to separately discuss the exact level of the influence of this value on occurrence of an error in determination between “normal” and “abnormal”.

Lastly, a used memory capacity and a computation rate will be described. In a method based on the data set DS, an increase in a size of a table makes it possible to increase accuracy. The capacity and the accuracy are thus in a trade-off relationship. However, assuming that the present estimated error of 1.5% is sufficiently accurate, the capacity that is necessary is not so large. First, the error is 1.5%, which does not necessitate use of a double-precision floating-point type for the table, and a single-precision floating-point type or an integer type is enough. When the single-precision floating-point type of 4 bytes is used, the capacity necessary for 10000 pieces of data included in the data set DS is approximately 40 KB. This is a capacity that is mountable on a very inexpensive microcomputer.

Next, as for the computation rate, it took 113 ms to calculate the estimated degree of abnormality Kᵢ′ based on the upper limit voltages Uᵢ and the lower limit voltages Lᵢ the number of which was 36000 in total using a cloud server of instance-type ml.c5.4xlarge available from Amazon Web Service. It is 3.1 μs per piece of data. It is unlikely to cause difficulty at least in selecting a microcomputer for data output for each 50 ms.

Next, the abnormality determiner 123d will be described.

The abnormality determiner 123d determines, based on the degree of abnormality determined by the degree-of-abnormality calculator 123c, whether the secondary battery has the risk of abnormality occurrence. The abnormality determiner 123d compares, for example, the degree of abnormality determined by the degree-of-abnormality calculator 123c with a threshold read from the storage 123b. If the degree of abnormality is smaller than the threshold as a result, the abnormality determiner 123d determines that the secondary battery has no risk of abnormality occurrence. In contrast, if the degree of abnormality is larger than or equal to the threshold, the abnormality determiner 123d determines that the secondary battery has the risk of abnormality occurrence. The abnormality determiner 123d outputs the determination result to the control part 310 via the communicator 130.

The low-pass filter 200 is a filter that removes the voltage spike to be inputted to the secondary battery pack 100 from the load 300. In an online environment, i.e., an environment in which the secondary battery pack 100 including the secondary battery 110 is coupled to the load 300 and in which the load 300 fluctuates, the voltage spike may be caused not only by the secondary battery 110 in which the micro-short circuit has occurred but also by the load 300. The low-pass filter 200 is provided to remove the voltage spike to be inputted to the secondary battery pack 100 from the load 300 in the online environment, and to prevent erroneous determination in the abnormality determiner 123. Accordingly, a circuit configuration (e.g., an RC low-pass filter) that may be a direct-current resistance component between the secondary battery 110 and the load 300 is not suitable for the low-pass filter 200.

The low-pass filter 200 is an LC low-pass filter. For example, as illustrated in FIG. 3, the low-pass filter 200 is a sixth-order LC low-pass filter. In FIG. 3, terminals 210 and 220 are coupled on a side of the secondary battery pack 100, and terminals 230 and 240 are coupled on a side of the load 300.

A cutoff frequency of the low-pass filter 200 is a frequency (e.g., 4 Hz) lower than a frequency (20 Hz) at which the voltage peak detector 122 transmits the maximum voltage Vu and the minimum voltage Vl. This aims at preventing data of the voltage spike derived from the secondary battery 110 from being easily buried in voltage change derived from the load 300 that fluctuates. That is, the data of the voltage spike outputted by the voltage peak detector 122 is data of a frequency component of 20 Hz, which is the frequency at which the voltage peak detector 122 transmits the maximum voltage Vu and the minimum voltage Vl. In contrast, because the cutoff frequency of the low-pass filter 200 is 4 Hz, even if the load 300 fluctuates at a rate of 20 Hz, the fluctuation is blocked by the low-pass filter 200 and does not reach the voltage peak detector 122. It is therefore possible to regard the frequency component of 20 Hz measured by the voltage peak detector 122 as the data purely derived from the secondary battery 110.

Next, in order to further deeply discuss the waveform of the voltage spike that occurs in the abnormal battery, a simulation using finite element method computation software, COMSOL Multiphysics, was carried out.

First, a cylindrical space having a diameter of 50 μm and a height of 50 μm was prepared in a simulation space. Thereafter, a cylindrical object having a diameter of 4 μm and a length of 25 μm was placed at the center of the space. The cylindrical object was a simulated body of a nickel dendrite having a metallic nickel physical constant. In the simulation, an upper surface of the cylindrical object was coupled to a positive electrode and a lower surface of the cylindrical object was coupled to a negative electrode (FIG. 11).

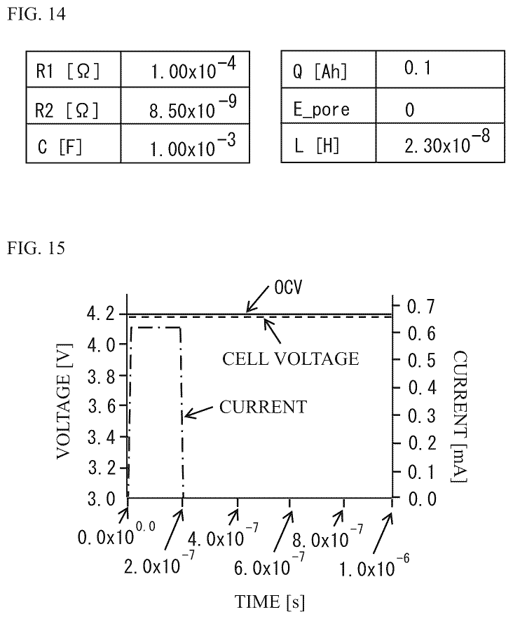

A potential difference V between the upper surface and the lower surface of the simulated body of nickel dendrite (i.e., a cell voltage when the simulated body of nickel dendrite was regarded as a battery) was assumed to be represented by the following equation.

$$\begin{matrix}[ Math . 7 ] & \\ V = {E}_{e q} ( θ ) - {R}_{i n t} \cdot {I}_{s c} - L \frac{{dI}_{s c}}{d t} & Math . 7\end{matrix}$$

Where E_{eq}(θ) is an equilibrium potential of the positive electrode, and θ is DOD defined by the following equation (FIG. 3). Further, Rᵢₙₜ is an internal resistance and is expressed by the following equation. Values of respective variables included in the above-described equations were as presented in FIG. 14, which were values assuming an actual battery of a coin type.

$$\begin{matrix}[ Math . 8 ] & \\ θ = \frac{1}{Q} \int {I}_{s c} \cdot dt & Math . 8\end{matrix}$$

$$\begin{matrix}[ Math . 9 ] & \\ {R}_{int} = {R}_{1} ( 1 - {e}^{\frac{t}{{CR}_{1}}} ) + {R}_{2} & Math . 9\end{matrix}$$

With settings described above, a time-dependent simulation was performed. It was assumed that the nickel dendrite had already been in contact with both the positive electrode and the negative electrode, i.e., a short-circuit had already occurred, at a timing of t=0 in the simulation. It was considered that the nickel dendrite was fused at a timing at which a maximum temperature of the nickel dendrite exceeded a melting point, and electronic conductivity of nickel was set to 0 so that a short-circuit current did not flow any more.

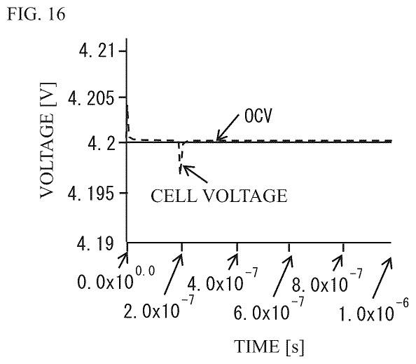

Results of the simulation are presented in FIGS. 15 and 16. A solid line represents OCV, a dashed line represents a value of V (i.e., the cell voltage) calculated by the above-described equation, and the dashed-dotted line represents a current passing through the dendrite. As a result of the simulation, the current became zero after 200 ns from a start of the simulation. The current was set to be zero at the timing when the maximum temperature of the nickel dendrite exceeded the melting point of nickel. In other words, the result was as follows: the maximum temperature of the nickel dendrite reached the melting point at approximately 200 ns in the simulation, and was fused. Referring to FIG. 16, the spike voltage on the upper side was observed when the short-circuit current began to flow, and the spike voltage on the lower side was observed when the fusing took place. Further, magnitudes of the spike voltages were on the order of microvolts.

The internal short circuit caused by the dendrite is instantaneous in time, but a significantly large current flows. When a current flows, a magnetic field is generated around the dendrite based on the Faraday effect. The voltage spike observed on each of the upper side and the lower side is considered to be a back electromotive force caused by rapid change in the current and the magnetic field.

In this simulation, it was found that the spike on the upper side and the spike on the lower side each had a significantly small time constant, which made it difficult to be detected unless a data logger of considerably high speed was used. Further, in this simulation, the spike on the upper side and the spike on the lower side were observed to be approximately the same in magnitude. A reason for this was considered that a shape of the dendrite did not change at all through the simulation. In practice, a change in the current over time may be asymmetric due to a difference between the shape when the current begins to flow and the shape when the fusing takes place. In other words, only the spike on the upper side may be observed to be particularly large, or only the spike on the lower side may be observed to be particularly large.

Through this simulation, it was found that the voltage spike caused by the internal short circuit of the dendrite could appear not only on the lower side but also on the upper side. It was also found that the time constant of the spike caused by the back electromotive force was significantly small, and that a high-speed data logger or the peak hold circuit as used in this method was therefore necessary in order to detect the spike on the upper side.

Next, effects of the electronic equipment 1 according to the present embodiment will be described.

According to the present embodiment, the degree of abnormality is calculated, based on the data set DS obtained from the multiple normal secondary batteries, for the feature obtained from the result of the measurement performed on the secondary battery. The data set DS is used each time the degree of abnormality is calculated. This makes it possible to detect the presence or absence of the abnormality in the secondary battery caused by the micro-short circuit, without using a technique having a high black-box property such as the neural network. Accordingly, it is possible for a user to understand and appropriately use a basis of the detection.

According to the present embodiment, the peak hold circuit is provided that holds the peak value of at least one of the voltage spike having the peak in the positive direction or the voltage spike having the peak in the negative direction. This makes it possible, even when an inexpensive AD converter having a low-sampling frequency is used, to detect a voltage spike that occurs in a much shorter time than a sampling interval.

According to the present embodiment, the data set DS includes the degree of abnormality of each of the multiple specific points in the four-dimensional feature space. The degree of abnormality is derived by the k-nearest neighbor algorithm based on the four kinds of features obtained from each of the normal secondary batteries in the four-dimensional feature space. This makes it possible to calculate the degree of abnormality of the determination target point by performing linear interpolation in the four-dimensional feature space based on the coordinates of the multiple specific points that are located in the vicinity of the determination target point. As a result, it is not necessary to use the k-nearest neighbor algorithm each time the presence or absence of the abnormality in the secondary battery caused by the micro-short circuit is determined. It is therefore possible to significantly reduce, as compared with a case where such calculation is performed, an amount of calculation and calculation time.

According to the present embodiment, among the wiring coupling the secondary battery 110 and the load 300 to each other, the low-pass filter 200 is interposed between the voltage measurer 121 and the load 300. This makes it possible to eliminate the voltage spike derived from the load even in the online environment in which the load 300 fluctuates. As a result, it is possible for the voltage peak detector 122 to correctly detect the voltage spike derived from the secondary battery 110, which makes it possible to correctly determine the abnormality of the secondary battery 110 caused by the micro-short circuit.

According to the present embodiment, at least one of the maximum voltage Vu or the minimum voltage Vl in every time period ΔT that is longer than the half-value width of the voltage spike is sequentially outputted from the voltage peak detector 122 to the abnormality determiner 123 at 1/time period ΔT [Hz]. This makes it possible, even when an inexpensive AD converter having a low-sampling frequency is used, to detect a voltage spike that occurs in a much shorter time than the sampling interval.

According to the present embodiment, the cutoff frequency of the low-pass filter 200 is a frequency [Hz] lower than 1/time period ΔT [Hz]. Thus, even if the load 300 fluctuates at a rate of 1/time period ΔT [Hz], the fluctuation is blocked by the low-pass filter 200 and does not reach the voltage peak detector 122. It is therefore possible to regard the frequency component of 1/time period ΔT [Hz] measured by the voltage peak detector 122 as the data purely derived from the secondary battery 110.

Next, modifications of the electronic equipment 1 according to an embodiment will be described.

In the embodiment described above, the data set DS may include the four kinds of features Cᵢ⁽¹⁾, Cᵢ⁽²⁾, Cᵢ⁽³⁾, and Cᵢ⁽⁴⁾ of the multiple (M-number of) normal secondary batteries illustrated in FIG. 5. In this case, the degree-of-abnormality calculator calculates, based on the data set DS including the four kinds of features Cᵢ⁽¹⁾, Cᵢ⁽²⁾, Cᵢ⁽³⁾, and Cᵢ⁽⁴⁾ of the multiple (M-number of) normal secondary batteries illustrated in FIG. 5, the degree of abnormality of the four kinds of features Cᵢ⁽¹⁾, Cᵢ⁽²⁾, Cᵢ⁽³⁾, and Cᵢ⁽⁴⁾ calculated by the feature calculator 123a. The degree-of-abnormality calculator 123c uses the data set DS each time the degree-of-abnormality calculator 123c calculates the degree of abnormality. The degree-of-abnormality calculator 123c calculates the degree of abnormality of the four kinds of features Cᵢ⁽¹⁾, Cᵢ⁽²⁾, Cᵢ⁽³⁾, and Cᵢ⁽⁴⁾ calculated by the feature calculator 123a, by the k-nearest neighbor algorithm based on the four kinds of features Cᵢ⁽¹⁾, Cᵢ⁽²⁾, Cᵢ⁽³⁾, and Cᵢ⁽⁴⁾, of the multiple (M-number of) normal secondary batteries, that are included in the data set DS.

With this configuration, it is necessary to use the k-nearest neighbor algorithm each time the presence or absence of the abnormality in the secondary battery caused by the micro-short circuit is determined. This causes the amount of calculation and the calculation time to be enormous as compared with the above-described embodiment, but makes it possible to reduce errors in the degree of abnormality. Further, effects similar to those of the above-described embodiment are achievable except for those regarding the amount of calculation and the calculation time.

As described above, the four kinds of features are calculated in order to determine the presence or absence of the abnormality in the secondary battery caused by the micro-short circuit. However, the number of kinds of features for determining the presence or absence of the abnormality in the secondary battery caused by the micro-short circuit is not limited to four, and may be two or three, or may be five or more.

As described above, the degree of abnormality is calculated by the k-nearest neighbor algorithm. However, the degree of abnormality may be calculated by, for example, any one of a subspace method, a recurrent neural network, an autoencoder, or a one-class support vector machine method, based on the data set DS. With this configuration, it is also possible for a user to understand and appropriately use a basis of the detection.

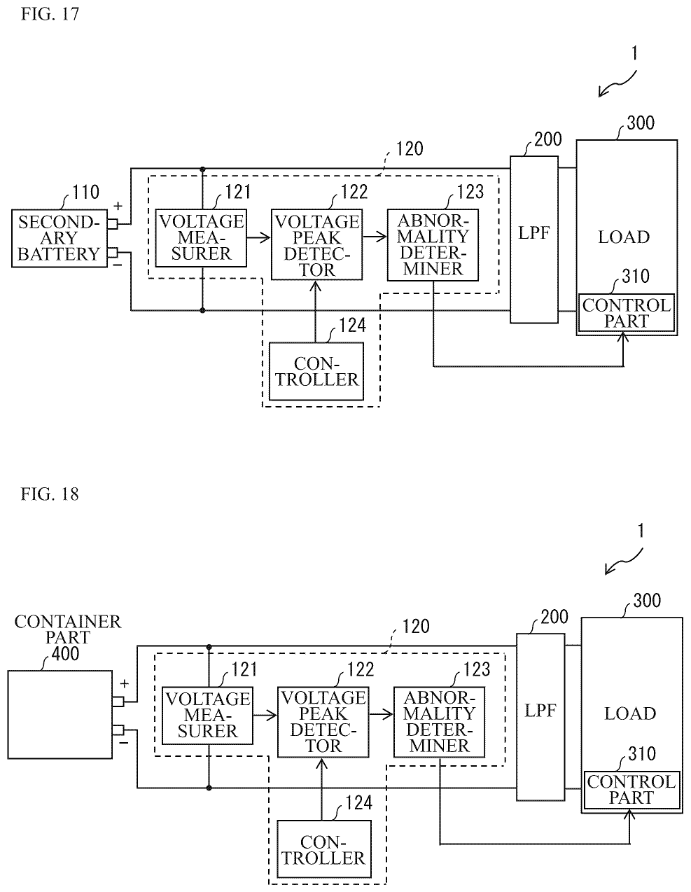

As described above, the abnormality determination device 120 is disposed inside the secondary battery pack 100. However, the secondary battery 110 and the abnormality determination device 120 may be provided separately from each other, as illustrated in FIG. 17. In other words, the abnormality determination device 120 may be provided outside the secondary battery pack 100. In this case, with this configuration, effects similar to those of the above-described embodiment are also achievable.

As illustrated in FIG. 18, for example, the electronic equipment 1 described above may include a container part 400 to and from which the secondary battery 110 is attachable and detachable. In this case, the secondary battery 110 is contained inside the container part 400 to thereby make it possible to electrically couple the secondary battery 110 and the load 300 to each other. With this configuration, effects similar to those of the above-described embodiment are also achievable.

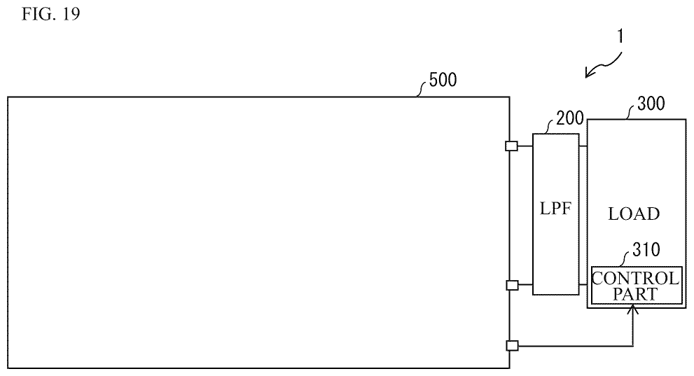

As illustrated in FIG. 19, for example, the electronic equipment 1 described above may include a container part 500 to and from which the secondary battery pack 100 is attachable and detachable. In this case, the secondary battery pack 100 is contained inside the container part 500 to thereby make it possible to electrically couple the secondary battery pack 100 and the load 300 to each other. With this configuration, effects similar to those of the above-described embodiment are also achievable.

As described above, the low-pass filter 200 is disposed outside the secondary battery pack 100. However, in the embodiment and Modifications A to F described above, the low-pass filter 200 may be provided inside the secondary battery pack 100. With this configuration, effects similar to those of the above-described embodiment are also achievable.

The effects described herein are mere examples, and effects of the present technology are therefore not limited to those described herein. Accordingly, the present technology may achieve any other effect.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. An abnormality detection device comprising:
a voltage measurer that measures a voltage of a secondary battery;
a voltage holder that holds a voltage value of at least one of a maximum value or a minimum value, of the voltage measured by the voltage measurer, in every fixed time period;
a feature calculator that calculates a feature that has sensitivity to a voltage spike waveform by processing the voltage value held in the voltage holder;
a data set holder that holds a data set obtained from a normal secondary battery; and
a degree-of-abnormality calculator that calculates, based on the data set read from the data set holder, a degree of abnormality of the feature calculated by the feature calculator.

2. The abnormality detection device according to claim 1, wherein the degree-of-abnormality calculator uses the data set each time the degree-of-abnormality calculator calculates the degree of abnormality.

3. The abnormality detection device according to claim 1, wherein the voltage holder includes at least one of a peak hold circuit that holds a peak value of a voltage spike having a peak in a positive direction included in the voltage measured by the voltage measurer, or a peak hold circuit that holds a peak value of a voltage spike having a peak in a negative direction included in the voltage measured by the voltage measurer.

4. The abnormality detection device according to claim 1, wherein
the feature calculator calculates, as the feature, m-number of kinds of features, the m-number being greater than or equal to 2,
the data set includes m-number of kinds of features obtained from the normal secondary battery, and
the degree-of-abnormality calculator calculates, by a k-nearest neighbor algorithm, a degree of abnormality of the m-number of kinds of features of the secondary battery, the k-nearest neighbor algorithm being based on the m-number of kinds of features of the normal secondary battery that are included in the data set and the m-number of kinds of features of the secondary battery calculated by the feature calculator.

5. The abnormality detection device according to claim 1, wherein
the feature calculator calculates, as the feature, m-number of kinds of features, the m-number being greater than or equal to 2,
the data set includes a degree of abnormality of each of multiple specific points, the degree of abnormality being derived by a k-nearest neighbor algorithm, the k-nearest neighbor algorithm being based on m-number of kinds of features obtained from the normal secondary battery and coordinates of the specific points in a m-number-dimensional feature space having the m-number of kinds of features as respective dimensions, and
the degree-of-abnormality calculator calculates, based on the degree of abnormality of each of the specific points included in the data set, a degree of abnormality of the m-number of kinds of features calculated by the feature calculator.

6. The abnormality detection device according to claim 1, wherein the degree-of-abnormality calculator calculates a degree of abnormality of the feature calculated by the feature calculator, the degree-of-abnormality calculator calculating the degree of abnormality by any one of a subspace method, a recurrent neural network, an autoencoder, or a one-class support vector machine method that are based on the data set read from the data set holder.

7. An electric power source system comprising:
a secondary battery;
a voltage measurer that measures a voltage of the secondary battery;
a voltage holder that holds a voltage value of at least one of a maximum value or a minimum value, of the voltage measured by the voltage measurer, in every fixed time period;
a feature calculator that calculates a feature that has sensitivity to a voltage spike waveform by processing the voltage value held in the voltage holder;
a data set holder that holds a data set obtained from a normal secondary battery; and
a degree-of-abnormality calculator that calculates, based on the data set read from the data set holder, a degree of abnormality of the feature calculated by the feature calculator.

8. An abnormality detection method comprising:
measuring a voltage of a secondary battery;
holding a voltage value of at least one of a maximum value or a minimum value, of the voltage that has been measured, in every fixed time period;
calculating a feature that has sensitivity to a voltage spike waveform by processing the voltage value that has been held; and
calculating, based on a data set obtained from a normal secondary battery, a degree of abnormality of the feature.
